(19) United States
(12) Patent Application Publication
(10) Pub. No.: US 2020/0058624 A1
(43) Pub. Date: Feb. 20, 2020

(54) MICRO-LED DISPLAY DEVICE

(71) Applicant: PLAYNITRIDE INC., Tainan City (TW)

(72) Inventors: Po-Jen SU, Tainan City (TW); Gwo-Jiun SHEU, Tainan City (TW); Chun-Ming TSENG, Tainan City (TW)

(73) Assignee: PLAYNITRIDE INC., Tainan City (TW)

(21) Appl. No.: 16/222,695

(22) Filed: Dec. 17, 2018

(30) Foreign Application Priority Data
Aug. 17, 2018 (TW) 107128771

(51) Int. Cl. H01L 25/075; H01L 33/48; H01L 33/58

(52) U.S. Cl. CPC H01L 25/0753; H01L 33/58; H01L 33/483

(57) ABSTRACT

A micro light-emitting diode display device is disclosed in the present disclosure. The micro light-emitting diode display device includes a substrate and a plurality of display units. The substrate has a supporting surface. The plurality of display units is disposed on the substrate, with each of the plurality of display units including a plurality of micro light-emitting diodes, wherein a gap existing between any two of the plurality of display units next to each other has a varying width.

### CROSS-REFERENCE TO RELATED APPLICATIONS

This non-provisional application claims priority under 35 U.S.C. § 119(a) on Patent Application No(s). 107128771 filed in Taiwan, R.O.C. on Aug. 17, 2018, the entire contents of which are hereby incorporated by reference.

### TECHNICAL FIELD

The disclosure relates to a micro-LED display device, more particularly to a micro-LED display device having structures of display units.

### BACKGROUND

With the developments of optoelectronic technologies, it has become a trend that optoelectronic elements are developed based on the miniaturization. Recently, since the improvements of manufacturing sizes of light-emitting diodes (LEDs) are significant, LEDs with sizes of micrometers are introduced, namely micro-LEDs. Currently, micro-LED displays, manufactured by arranging micro-LEDs in an array, draw increasing attentions in the market.

Micro-LED displays are active light-emitting element displays. Comparing to OLED displays, the micro-LED displays has better power savings and contrast performances so as to be visible under the sunlight. In addition, due to the use of inorganic materials, the micro-LED displays have better reliabilities and longer lifetimes than the OLED displays.

In general, since different industries may demand LED display panels with different sizes, it would be necessary that LED display panels are cut and spliced to form a variety of LED displays having different sizes in the process of the LED display panels, so that the demands of different industries can be met. However, the problems of poor cutting yields and thermal expansions after splicing regarding the conventional LED display panel exist and are needed to be solved by persons in the related field.

### SUMMARY

A micro light-emitting diode display device is disclosed according to one embodiment of the present disclosure. The micro light-emitting diode display device includes a substrate and a plurality of display units. The substrate has a supporting surface. The plurality of display units is disposed on the supporting surface of the substrate, with each of the plurality of display units including a plurality of micro light-emitting diodes, wherein a gap existing between any two of the plurality of display units next to each other has a varying width.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a top view of a micro-LED display device according to one embodiment of the present disclosure;

FIG. 2 is a sectional view of the micro-LED display device according to the embodiment of FIG. 1;

FIG. 3 is a top view of a micro-LED display device according to another embodiment of the present disclosure;

FIG. 4A is a sectional view of the micro-LED display device according to the embodiment of FIG. 3;

FIG. 4B is a sectional view of a micro-LED display device according to another embodiment of the present disclosure;

FIG. 5 is a sectional view of a micro-LED display device according to another embodiment of the present disclosure; and

FIG. 6A to FIG. 6C are diagrams of cutting and splicing process for a micro-LED display device according to one embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

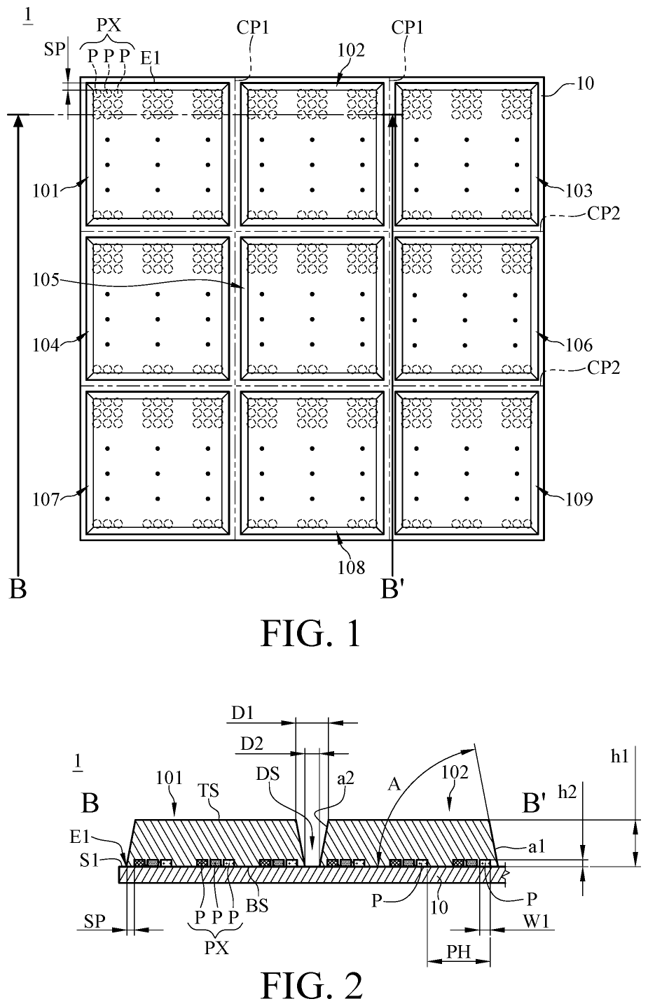

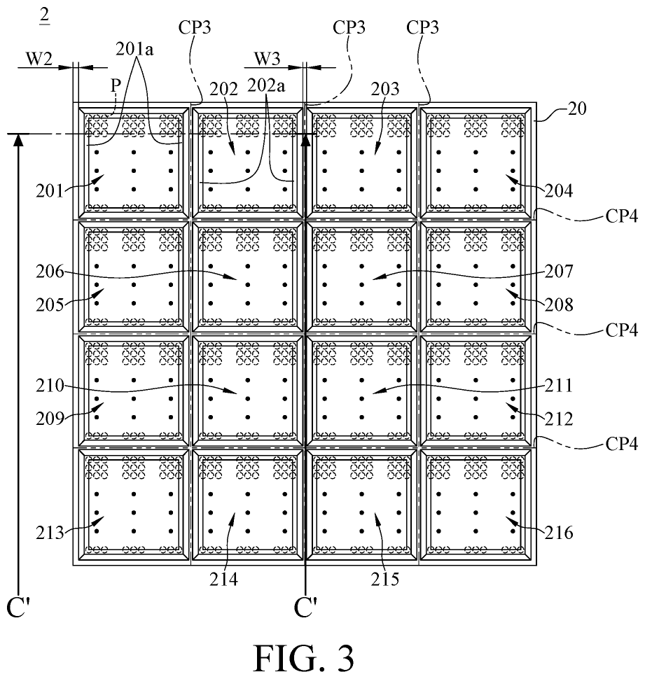

Please refer to FIG. 1 and FIG. 2. FIG. 1 is a top view of a micro-LED display device according to one embodiment of the present disclosure. FIG. 2 is a sectional view of the micro-LED display device according to the embodiment of FIG. 1. Specifically, FIG. 2 stands for a sectional view of the micro-LED display device along a sectional line BB′ in the embodiment of FIG. 1. As shown in figures, the micro-LED display device 1 includes a substrate 10 and a plurality of display units 101-109, and the substrate 10 has a supporting surface S1. In practice, the substrate 10 could be a printed circuit board (PCB), a flexible printed circuit board (FPCB), a thin film transistor (TFT) glass backplane, a glass backplane with connection wires, an integrated circuit (IC) or other driving substrate with operation circuits. A plurality of display units 101-109 are disposed on the supporting surface S1 of the substrate 10, and each of the plurality of display units includes a plurality of micro LEDs P. The plurality of display units 101-109 are electrically connected to the substrate 10, so that the control elements such as driving ICs, disposed on the substrate 10, are capable of driving the micro LEDs P via the electrical connection. In this embodiment, each of the plurality of display units includes a plurality of pixels PX, and each of the plurality of pixels PX includes at least three different color micro LEDs P such as a red micro LED, a green micro LED and a blue micro LED. Each of the color micro LEDs has a maximum side length of 3-150 micrometers. However, the present disclosure is not limited to the above embodiment.

In an implementation, the micro-LED display device 1 may include other components such as a memory, a touch screen controller and a battery, etc. However, the present disclosure is not limited to the above implementation. In other implementation, the micro-LED display device 1 could be a television, a tablet, a laptop, a computer monitor, an independent terminal server, a digital camera, a handheld game console, a media display, an e-book display, a vehicle display or a large electronic board display. Comparing to the general LED techniques with sizes of millimeters, the LED techniques with sizes of micrometers are applied to display panels so that the high resolutions and the lower power consumptions can be achieved. In addition, the micro-LED display panel has the advantages of power saving, simple structure and thin shape.

In this embodiment, a gap exists between any adjacent two of those display units 101-109 of the micro-LED display device 1, and the gap has a varying width. In the embodiment of FIG. 2, a gap DS exists between the display unit 101 and the display unit 102 adjacent to each other, and the gap DS has a varying width. In one embodiment as shown in FIG. 2, the varying width of the gap DS near the substrate 10 has a first value and the varying width of the gap DS away from the substrate 10 has a second value, with the first value smaller than the second value, so that a better alignment tolerance can be obtained in a splicing process of the display panel to improve the manufacturing yields. Specifically, the varying width of the gap DS increases gradually in the direction away from the substrate 10. Here, the varying width of the gap DS increases continuously in the direction away from the substrate 10. Not shown in the embodiment, the varying width of the gap increase discontinuously in the direction away from the substrate 10. For example, a stepped type of increasing may exist. In the embodiment of FIG. 2, the varying width of the gap DS has a maximum value D1 and a minimum value D2. In one example, the ratio of the minimum value D2 to the maximum value D1 is greater than or equal to 0.8 and less than or equal to 0.95. The ratio greater than 0.95 will result in the inevitability of the problem of thermal expansion caused by splicing for the display panel while the ratio less than 0.8 will result in a poor light pattern. In another example, the minimum value D2 is less than 200 micrometers and greater than or equal to 20 micrometers. In this example, the minimum value D2 is limited to be in the range which is less than 200 micrometers and greater than or equal to 20 micrometers, so as to overcome the problem of poor display panel quality caused by splicing seams.

From the view of implementation, the micro-LED display device provided by the present disclosure could be considered as a display panel mold during the manufacturing process. The display units 101-109 are display packages disposed in the display panel. Gaps are reserved between the display packages, so that the display panel can be easily divided into several sub-panels for splicing. In one embodiment, a cutting line is defined on the supporting surface S1 of the substrate 10, and the cutting line is located between any two adjacent display units. As shown in FIG. 1, the vertical cutting line CP1 is located, for example, between the two adjacent display units 101 and 102, the two adjacent display units 104 and 105 and the two adjacent display units 107 and 108. In addition, the horizontal cutting line CP2 is located, for example, between the two adjacent display units 101 and 104, the two adjacent display units 102 and 105 and the two adjacent display units 103 and 106.

The cutting line CP1 is located in the gap between the display units 101 and 102, the gap between the display units 104 and 105, and the gap between the display units 107 and 108. The cutting line CP2 is located in the gap between the display units 101 and 104, in the gap between the display units 102 and 105, and the gap between the display units 103 and 106. In one embodiment, the distance between a cutting line and an edge of one of any two adjacent display units on the substrate 10 is less than 100 micrometers. For example, the distance between the cutting line CP1 and the edge of the display unit 101 and/or the display unit 102 on the substrate 10 is less than 100 micrometers. Thereby, the problem of poor display quality caused by the significant splicing seams of the micro-LED display device can be improved.

Each of the plurality of display units has a top surface away from the supporting surface S1 and a bottom surface adjacent to the supporting surface S1. The display unit 101 is taken as an example, as shown in FIG. 2, the display unit 101 has a top surface TS away from the supporting surface S1 and a bottom surface adjacent to the supporting surface S1. An orthogonal projection area of the top surface TS on the substrate 10 is less than an orthogonal projection area of the bottom surface BS on the substrate 10. In other words, the area of the top surface TS is less than the area of the bottom surface BS. In one example, the ratio of the orthogonal projection area of the top surface TS on the substrate 10 to the orthogonal projection area of the bottom surface BS on the substrate 10 is greater than or equal to 0.8 and less than or equal to 0.95. The ratio greater than 0.95 will result in the inevitability of the problem of thermal expansion caused by splicing for the display panel while the ratio less than 0.8 will result in a poor light pattern. In an implementation, a technique of surface roughening can be applied to the top surface of the display unit so as to increase light emitting efficiency.

In one embodiment, the sum of orthogonal projection areas of the display units 101-109 on the substrate 10 is less than the area of the supporting surface S1. In a practical example, the ratio of the sum of orthogonal projection areas of the display units 101-109 on the substrate 10 to the area of the supporting surface S1 is greater than or equal to 0.8 and less than or equal to 0.95. More specifically, the sum of orthogonal projection areas of the display units 101-109 on the substrate 10 is equivalent to the sum of the bottom areas of the display units 101-109. Since there are gaps reserved between the bottom surfaces of the adjacent display units adapted for cutting operations, the sum of the bottom areas of the display units 101-109 will slightly less than the area of the supporting surface S1. Thereby, a better yield can be achieved in the operations of cutting.

In one embodiment, each of the display units has a plurality of side surfaces, and each of the plurality of side surfaces forms an angle A with the supporting surface S1 of the substrate 10, wherein the angle A is between 20 to 80 degrees. In the sectional view shown in FIG. 2, the display unit 102 has side surfaces a1 and a2, wherein the side surface a1 forms the angle A with the supporting surface S1 of the substrate 10. More specifically, each of the plurality of display units has four side surfaces, with each of the side surfaces adjacent to the top surface and the bottom surface. Since the area of each of the top surfaces is less than the area of each of the bottom surface, the angle can be formed by each of the side surfaces and the supporting surface S1. Due to the features of the angle structures, the section of each of the display units is presented in a trapezoid shape. As shown in the sectional view of FIG. 2, both of the display units 101 and 102 are presented in a trapezoid shape. In another embodiment, the angle formed by the four side surfaces and the bottom surface of each of the display units is determined based on the actual demands. In another embodiment, the section of each of the display units is presented in a stepped shape. However, the present disclosure is not limited to the section types of the display units mentioned in the above embodiment.

In one embodiment, the height of each of the micro LEDs is less than the height of each of the display units. More specifically, the ratio of the height of each of the micro LEDs to the height of each of the display units is less than 0.15. In the embodiment of FIG. 2, the ratio of the height h2 of each of the micro LEDs P to the height h1 of the display unit 102 is less than 0.15. In a preferable embodiment, the height h1 of the display unit may be between 40-250 micrometers. By taking the advantage of the height, the display unit has a better light pattern and the light emitting of the display unit would not be affected. In one embodiment, each of the display units has the height H, each of the micro LEDs has the width W, and the angle A is formed by the side surface and the supporting surface. An inequality,

$$\frac{H}{tan ( A )} < \frac{Pitch - W}{2} ,$$

is held, wherein the “pitch” stands for a space between any two adjacent pixels in the display unit. In the embodiment of FIG. 2, the display unit 102 has the height h1, an angle A is formed by the side surface a1 and the supporting surface S1, each of the micro LEDs P in the display unit 102 has the width W1, and a space PH exists between the adjacent pixels. Those parameters mentioned above are inputted into the above formula to obtain the relationship:

$$\frac{h 1}{tan ( A )} < \frac{PH - W 1}{2} .$$

In one embodiment, the edge of each of the display units on the substrate is adjacent to and spaced from a portion of the micro LEDs for a distance less than 600 micrometers. Specifically, an edge of a display unit on the substrate is the junction between a side surface of the display unit and the supporting surface of the substrate, such as the edge μl as shown in FIG. 1 and FIG. 2. The distance SP between the several micro LEDs P adjacent to the edge μl and the edge μl is less than 600 micrometers, so that the display unit has a better light pattern and light emitting would not be affected negatively.

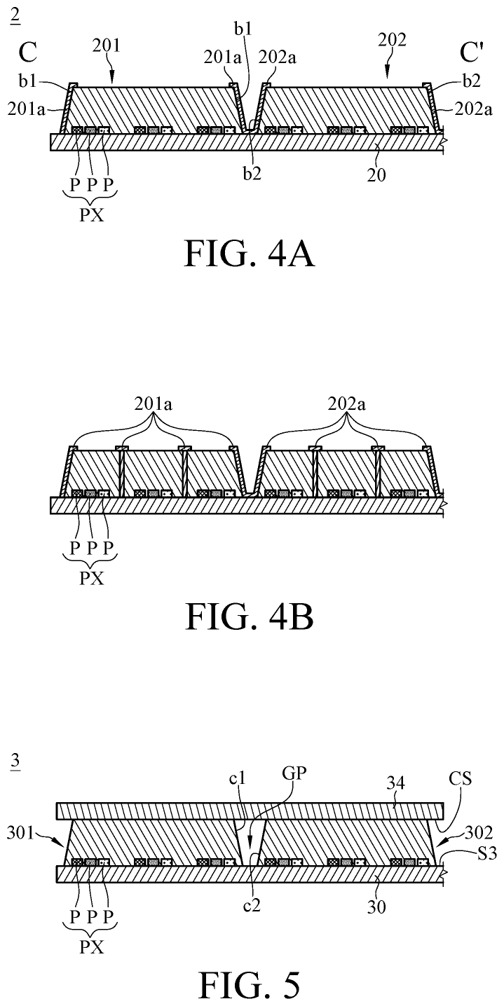

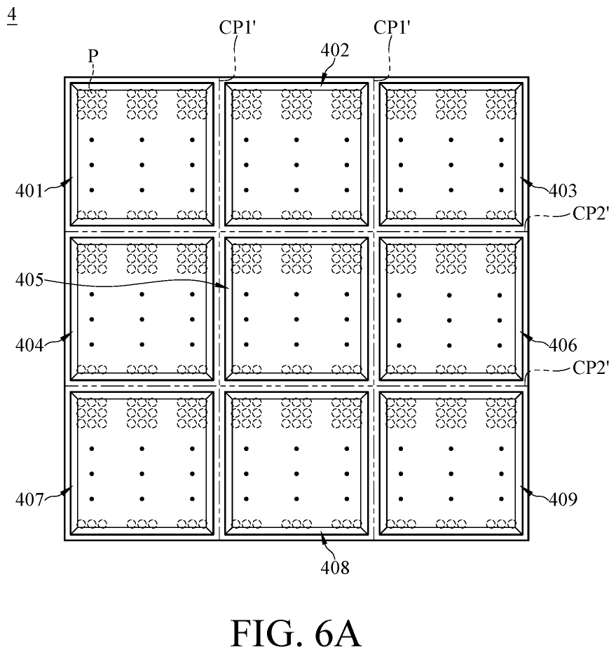

Please refer to FIG. 3 and FIG. 4A. FIG. 3 is a top view of a micro-LED display device according to another embodiment of the present disclosure, and FIG. 4A is a sectional view of the micro-LED display device according to the embodiment of FIG. 3. Specifically, FIG. 4A stands for a sectional view of the micro-LED display device along the sectional line CC′ in the embodiment of FIG. 3. The micro-LED display device 2 shown in FIG. 3 and FIG. 4A basically has the same structure as the micro-LED display device 1 shown in FIG. 1 and FIG. 2. As shown in the top view of FIG. 3, the micro-LED display device 2 has a plurality of display units 201-216 disposed on the substrate 20 and each of them includes a plurality of micro LEDs P. A plurality of vertical cutting lines CP3 and horizontal cutting lines CP4 are disposed on the substrate 20. The difference between the embodiments of FIG. 1-2 and the embodiments of FIG. 3-4A lies in that the micro-LED display device 2 shown in FIG. 3 and FIG. 4A further includes a plurality of shading structures, and each of the plurality of shading structures covers the top surface of the respective display unit. In the sectional view of the embodiment of FIG. 4A, the shading structure 201a covers the top surface of the display unit 201 while the shading structure 202a covers the top surface of the display unit 202. In one example, the ratio of the covering area of each of the shading structures on the top surface of the respective display unit to the area of the top surface of the respective display unit is greater than or equal to 0.5 and less than or equal to 0.95. In other words, the shading structure only covers part of the top surface of the respective display unit instead of fully covering the top surface of the respective display unit. In practice, the shading structures are black matrix (BM) layers, consisting of black resist materials and adapted for preventing light leakages from happening and enhancing the contrast of the display panel.

As described above, each of the display units has the side surfaces, and each of the shading structures fully cover the side surfaces of the respective display unit. As shown in the embodiment of FIG. 4A, the side surface b1 of the display unit 201 is fully covered by the shading structure 201a while the side surface b2 of the display unit 202 is fully covered by the shading structure 202a, so as to avoid the side light leakages. In one embodiment, the orthogonal projection of each of the shading structures on the substrate 20 cover the orthogonal projections of a portion of the micro LEDs in the respective display unit on the substrate 20. In the embodiment of FIG. 4A, the orthogonal projection of the shading structure 201a located on the display unit 201 on the substrate 20 covers the orthogonal projection of the micro LED P on the left side on the substrate 20. In the embodiment, the ratio of the overlapping area of the orthogonal projection of the shading structure 201a on the substrate 20 and the orthogonal projection of the micro LED P on the left side on substrate 20 to the area of the orthogonal projection of the micro LED P on the left side on substrate 20 is less than or equal to 0.4. The ratio greater than 0.4 will affect the light emitting.

In other words, the shading structure 201a covers a portion of the micro LED P on the left side, and the ratio of the covering area on the micro LED P on left side to the top area of the micro LED P on the left side is less than or equal to 0.4. In a preferable embodiment, the ratio of the covering area on the micro LED P on left side to the top area of the micro LED P on the left side is less than or equal to 0.1, so that the aperture ratio of light emitting is increased. It is noted that the shading structure may be further disposed between the respective pixels. Please refer to FIG. 4B, which is a sectional view of a micro-LED display device according to another embodiment of the present disclosure. As shown in FIG. 4B, the shading structure 201 on a display unit 201 is further disposed between pixels PX, so as to prevent cross talks caused by inter-influence of the light emitting of the pixels PX and enhance the contrast of the display panel. In the embodiments of FIG. 3, FIG. 4A and FIG. 4B, the shading structure covered on the display unit extends from the display unit to the cutting line CP3 on the supporting surface of the substrate 20. In other words, the shading structure is not limited to be disposed on the display unit only. Instead, the shading structure can be extended to the cutting line. In another embodiment, the shading structure only covers a portion of the top surface and the four side surfaces of the respective display unit without extending to the cutting line.

In one embodiment, for the purpose of reserving more spaces for wiring, the distance between the portion of the plurality of display units near the edge of the substrate and the edge of the substrate is greater than the distance between the other portion of the display units located in the central area of the substrate. In the top view of the embodiment of FIG. 3, the distances (e.g. W2) between those display units 201-205, 208, 209, 212 and 213-216 near the edge of the substrate 20 are relatively larger, and the distances (e.g. W3) between the display units 206, 207, 210 and 211 are relatively smaller. As a result, more spaces can be reserved for side wirings of the substrate so as to avoid the difficulty of wirings due to narrow spaces resulting in abnormal wire transmissions.

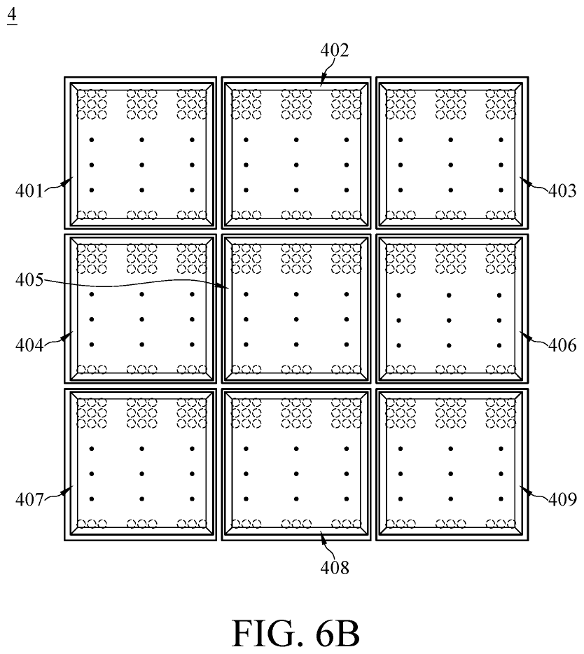

Please refer to FIG. 5, which is a sectional view of a micro-LED display device according to another embodiment of the present disclosure. The micro-LED display device 3 shown in FIG. 5 basically has the same structure as the micro-LED display device 1 shown in FIG. 2. As shown in the sectional view of FIG. 5, the micro-LED display device 3 has a plurality of display units 301-302 disposed on the substrate 30, and each of the plurality of display units 301-302 has a plurality of micro LEDs P. The difference between FIG. 2 and FIG. 5 lies in that the micro-LED display device 3 shown in FIG. 5 further includes a cover plate 34 covering the display units 301-302. In a practical example, the cover plate 34 is a glass cover plate, which has the size as same as or slightly larger than the substrate 30. As shown in FIG. 4, the cover plate 34 has a covering surface CS, which is connected to the top surfaces of the display units 301-302. The covering surface CS of the cover plate 34 faces the substrate 30. A portion of the covering surface CS forms a spacing GP with the side surfaces c1-c2 of the two adjacent display units 301-302 and a portion of the supporting surface S3. In this embodiment, the spacing GP is an air spacing, and the alignment tolerance of the display units can be increased in the cutting and splicing operations. In an embodiment not shown, the spacing GP could be a spacing filled with filling materials The refractive index of the filling materials may be larger than the refractive index of air and/or smaller than the refractive index of the shading structure.

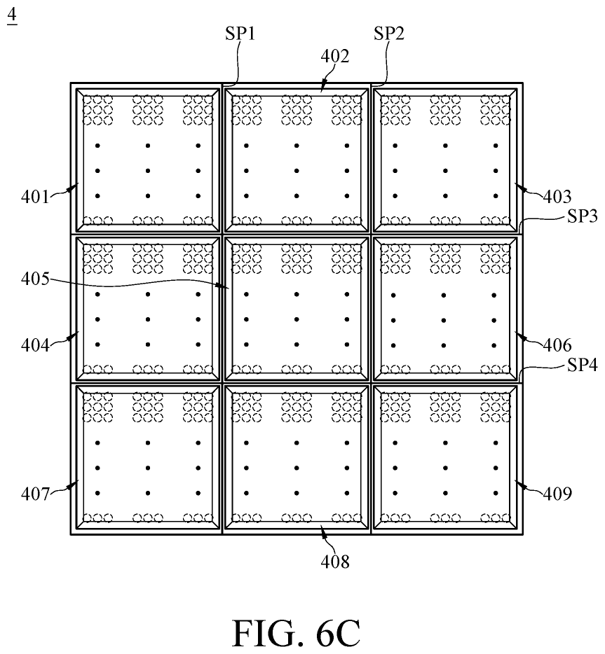

Please refer to FIG. 6A to FIG. 6C. FIG. 6A to FIG. 6C are diagrams of cutting and splicing process for a micro-LED display device according to one embodiment of the present disclosure. In general, in order to meet the demands for different display panel sizes in the market, it is necessary to perform a cutting and a splicing operation for a display panel mold in a display panel process, so as to form a display panel with a proper size. FIG. 6 shows a micro-LED display device 4 which has not been cut yet. The micro-LED display device 4 has a plurality of display units 401-409, and each of the plurality of display units 401-409 includes a plurality of micro LEDs P. The cutting lines are disposed in the gaps between the adjacent display units, such as the cutting lines CP1′-CP2′ shown in FIG. 6A. In the process, the micro-LED display device 4 can be cut along the cutting lines CP1′-CP2′ so as to obtain several independent sub-display units as shown in FIG. 6B. In the micro-LED display device provided by the present disclosure, the cutting lines are disposed in the gaps reserved between the plurality of display units, so that the cutting operation can be performed easily.

Then, the several independent display units 401-409 can be spliced together to form the micro-LED display device as shown in FIG. 6c. As described above, FIG. 6C shows the micro-LED display device 4 which has been spliced, and the splicing seams exist in the gaps between the adjacent display units of the micro-LED display device 4 which has been spliced, such as the splicing seams SP1-SP4. As described in the above embodiment, since the distance between the cutting line and the edge of one of the any two adjacent display units on the substrate 10 is extremely small, such as the distance less than 100 micrometers, the splicing seams SP1-SP4, formed by splicing the several independent display units, would be insignificant and the overall display quality would not be affected negatively.

Based on the above descriptions, in the micro-LED display device provided in the present disclosure, by taking the advantages of the structure in which gaps exist between the adjacent display units, the cutting operation can be easily performed so as to increase the cutting yield of the display panel. Moreover, the structure further improves the problem of thermal expansions caused after splicing the display panel.

What is claimed is:

1. A micro light-emitting diode display device, comprising:
a substrate having a supporting surface; and
a plurality of display units disposed on the supporting surface of the substrate, with each of the plurality of display units comprising a plurality of micro light-emitting diodes, wherein a gap existing between any two of the plurality of display units next to each other has a varying width.

2. The micro light-emitting diode display device according to claim 1, wherein the varying width of the gap near the substrate has a first value and the varying width the gap away from the substrate has a second value, with the first value smaller than the second value.

3. The micro light-emitting diode display device according to claim 2, wherein the varying width of the gap increases gradually in a direction away from the substrate.

4. The micro light-emitting diode display device according to claim 1, wherein the varying width of the gap has a maximum value and a minimum value, and a ratio of the minimum value to the maximum value is greater than or equal to 0.8 and less than or equal to 0.95.

5. The micro light-emitting diode display device according to claim 1, wherein each of the plurality of display units has a top surface away from the supporting surface and a bottom surface adjacent to the supporting surface, an orthogonal projection area of the top surface on the substrate is less than an orthogonal projection area of the bottom surface on the substrate.

6. The micro light-emitting diode display device according to claim 1, wherein a sum of orthogonal projection areas of the plurality of display units on the substrate is less than an area of the supporting surface.

7. The micro light-emitting diode display device according to claim 1, wherein a ratio of a height of each of the plurality of micro light-emitting diodes to a height of each of the plurality of display units is less than 0.15.

8. The micro light-emitting diode display device according to claim 1, further comprising:
a plurality of shading structures, with each of the plurality of shading structures covering a top surface of a respective one of the plurality of display units, and with a ratio of a covering area of each of the plurality of shading structures on the top surface of the respective display unit to an area of the top surface of the respective display unit greater than or equal to 0.5 and less than or equal to 0.95.

9. The micro light-emitting diode display device according to claim 8, wherein each of the plurality of display units has a side surface, and each of the plurality of shading structures fully covers the side surface of the respective display unit.

10. The micro light-emitting diode display device according to claim 8, wherein an orthogonal projection of each of the plurality of shading structures on the substrate covers orthogonal projections of a portion of the micro light-emitting diodes in the respective display unit on the substrate, a ratio of an overlapping area between the orthogonal projection of the shading structure on the substrate and the orthogonal projections of the portion of the micro light-emitting diodes on the substrate to the orthogonal projections of the portion of the micro light-emitting diodes on the substrate is less than or equal to 0.4.

11. The micro light-emitting diode display device according to claim 1, further comprising:
a cover plate covering the plurality of display units and having a covering surface facing the substrate, with a portion of the covering surface forming a spacing with sides surfaces of the any two of the plurality of display units adjacent to each other and a portion of the supporting surface.

12. The micro light-emitting diode display device according to claim 1, wherein an edge of each of the plurality of display areas on the substrate is adjacent to and spacing from edges of a portion of the plurality of micro light-emitting diodes for a distance less than 600 micrometers.

13. The micro light-emitting diode display device according to claim 1, wherein each of the plurality of display units has a plurality of side surfaces, each of the plurality of side surfaces forms an angle A with the supporting surface of the substrate, the angle A is between 20 to 80 degrees.

14. The micro light-emitting diode display device according to claim 13, wherein each of the plurality of display units has a height H, and each of the plurality of micro light-emitting diodes has a width W, each of the plurality of display units comprises a plurality of pixels, and each of the plurality of pixels comprises at least three different color light-emitting diodes, wherein
$$\frac{H}{tan ( A )} < \frac{Pitch - W}{2} ,$$
the pitch represents a spacing between any two of the plurality of pixels in the display unit.

15. The micro light-emitting diode display device according to claim 1, wherein a cutting line is defined on the supporting surface of the substrate, the cutting line is located in the gap between the any two of the plurality of display units adjacent to each other, a distance between the cutting line and an edge of one of the any two of the plurality of display units adjacent to each other on the substrate is less than 100 micrometers.

16. The micro light-emitting diode display device according to claim 15, wherein each of the any two of the plurality of display units adjacent to each other is covered with a shading structure, and the two shading structures extend to the cutting line on the supporting surface from the any two of the plurality of display units adjacent to each other.

17. The micro light-emitting diode display device according to claim 1, wherein a distance between edges of a portion of the plurality of display units near an edge of the substrate and an edge of the substrate is greater than a distance between edges of another portion of the plurality of display units located in a central area of the substrate.
